(19) United States
(12) Patent Application Publication
(10) Pub. No.: US 2010/0213462 A1
(43) Pub. Date: Aug. 26, 2010

(54) METAL OXIDE STRUCTURE AND METHOD FOR PRODUCING THE SAME, AND LIGHT-EMITTING ELEMENT

(75) Inventor: Tetsuo KAWANO, Ashigarakami-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/712,805

(22) Filed: Feb. 25, 2010

(30) Foreign Application Priority Data
Feb. 25, 2009 (JP) 2009-042340

(51) Int. Cl. H01L 33/00; H01L 21/04; H01L 29/12

(52) U.S. Cl. 257/43; 438/104; 257/103; 257/E21.04; 257/E29.068; 257/E33.013

(57) ABSTRACT

A method for producing a metal oxide structure, including: forming a layer containing metal acetate hydrate on a sapphire substrate; subjecting the layer containing the metal acetate hydrate to an insolubilization treatment; and immersing the sapphire substrate having the insolubilized layer in a reaction solution containing a metal ion and an NH₄⁺ ion, so as to grow rod-shaped crystals each containing metal oxide as a main substance thereof.

### BACKGROUND OF THE INVENTION

1. Field of the Invention

The present invention relates to a metal oxide structure suitably used for a light-emitting element, a highly sensitive sensor, and the like, a method for producing the metal oxide structure, and a light-emitting element having the metal oxide structure.

2. Description of the Related Art

Conventionally, various structures, in which whisker-shaped and/or needle-like shaped metal oxide crystals formed standing upright on a substrate, have been proposed.

For example, Japanese Patent Application Laid-Open (JP-A) No. 2006-96591 proposes a method, in which a substrate having a crystal surface which contains a material containing a metal having a structure in which crystals are regularly oriented in a certain direction (for example, a perpendicular direction to a c-plane sapphire substrate) is immersed in a reaction solution which enables metal oxide to deposit, so as to deposit metal oxide crystals on the crystal surface. According to this method, a metal oxide structure having a needle-like shape or a rod-shape can be effectively produced.

However, in JP-A No. 2006-96591 seed crystal particles, namely, a core for starting crystal growth is not present, and rod-shaped crystals each having a small diameter cannot be obtained. Thus, a metal oxide structure in which the rod-shaped crystals are formed on the substrate with high orientation and high density cannot be obtained. On the other hand, even though a layer of seed crystal particles (intermediate layer (template layer)) are formed by heating a sol-gel film of zinc oxide at a temperature of 400° C., the orientation of the rod-shaped crystals formed on the substrate is decreased. That is, the metal oxide structure in which the rod-shaped crystals are formed on the substrate with high orientation and high density cannot be obtained.

Moreover, in Journal of Colloid and Interface Science. 325, 459-463 (2008), X. L. Hu, Y. Masuda, T. Ohji and K. Kato propose a method in which a coating solution containing metal acetate hydrate is applied to a glass substrate coated with fluorine doped tin oxide, and heated at 65° C. for 24 hours to dehydrate the metal acetate hydrate, to thereby form an intermediate layer (template layer), and followed by forming rod-shaped crystals of zinc oxide. This method can form the intermediate layer (template layer) by heating at lower temperature than that in conventional methods, and can use for a substrate having low heat resistance.

However, according to Journal of Colloid and Interface Science. 325, 459-463 (2008) reported by X. L. Hu et al., the metal oxide structure in which the rod-shaped crystals are formed on the substrate with high orientation and high density cannot be obtained.

Moreover, X. L. Hu et al., in Journal of Colloid and Interface Science. 325, 459-463 (2008) and X. L. Hu, Y. Masuda, T. Ohji and K. Kato, in Langmuir, 24, 7614-7617 (2008) respectively propose a method in which a coating solution containing metal acetate hydrate is applied to a glass substrate coated with fluorine doped tin oxide, and irradiated with ultraviolet light for 1 hour at normal pressure to dehydrate the metal acetate hydrate, to thereby form an intermediate layer (template layer), and followed by forming rod-shaped crystals of zinc oxide.

However, by the method described in Langmuir, 24, 7614-7617 (2008) reported by X. L. Hu, Y. Masuda, T. Ohji and K. Kato, the metal oxide structure in which the rod-shaped crystals are formed on the substrate with high orientation and high density cannot be obtained.

In Journal of Applied Physics. 85, 2595-2602 (1999), C. R. Gorla et al. propose a method for forming a zinc oxide layer by metal organic chemical vapor deposition.

However, by the method disclosed in Journal of Applied Physics. 85, 2595-2602 (1999) reported by C. R. Gorla et al., the metal oxide structure in which the rod-shaped crystals are formed on the substrate with high orientation and high density cannot be obtained.

In Journal of The Electrochemical Society, 146, 4517-4521 (1999), M. Izaki proposes a method for forming a zinc oxide layer by an electrochemical deposition.

However, the method described in Journal of The Electrochemical Society, 146, 4517-4521 (1999) reported by M. Izaki needs electricity, and by the method the metal oxide structure in which the rod-shaped crystals are formed on the substrate with high orientation and high density cannot be obtained. A method for forming a Zn₁₋ₓMgₓO layer by an electrochemical deposition is proposed by H. Ishizaki and N. Yamada, in Electrochemical and Solid-State Letters, 9, C178-C180 (2006), and H. Ishizaki and H Maeda, in “Electrochemical Fabrication of Zn₁₋ₓMgₓO Films from an Aqueous Solution Containing Magnesium Nitrate and Zinc Sulfate” Zinc Oxide and Related Materials-2007MRS Proceedings Volume 1035E (Electronic content only—No book published) 1035-L05-25.

However, the method described in Electrochemical and Solid-State Letters, 9, C178-C180 (2006) reported by H. Ishizaki and N. Yamada, and “Electrochemical Fabrication of Zn₁₋ₓMgₓO Films from an Aqueous Solution Containing Magnesium Nitrate and Zinc Sulfate” Zinc Oxide and Related Materials-2007MRS Proceedings Volume 1035E (Electronic content only—No book published) 1035-L05-25 reported by H. Ishizaki and H Maeda needs electricity, and by the method the metal oxide structure in which rod-shaped crystals are formed on the substrate with high orientation and high density cannot be obtained.

Therefore, the metal oxide structure in which the rod-shaped crystals are formed on the substrate with high orientation and high density, and the method for effectively producing the metal oxide structure have not been provided yet at present.

### BRIEF SUMMARY OF THE INVENTION

The present invention aims to solve the conventional problems and achieve the following objects. That is, an object of the present invention is to provide a metal oxide structure which includes rod-shaped crystals formed on a substrate with high orientation and high density, and is useful as a light-emitting element, a high sensitive sensor, and the like, and a method for producing the metal oxide structure, and a light-emitting element.

Another object of the present invention is to provide the method for producing the metal oxide structure, which can effectively produce the metal oxide structure at low cost by a wet process.

The inventors of the present invention have been studied to achieve the objects, and found that a metal oxide structure, which includes rod-shaped crystals formed on a substrate with high orientation and high density, and can be produced by forming a layer containing metal acetate hydrate on a sapphire substrate, subjecting the layer containing the metal acetate hydrate to an insolubilization treatment, and immersing the sapphire substrate having the insolubilized layer in a reaction solution.

The present invention is based on the above-mentioned findings by the inventors and a means for solving the above-mentioned problems is as follows.
<1> A method for producing a metal oxide structure, including: forming a layer containing metal acetate hydrate on a sapphire substrate; subjecting the layer containing the metal acetate hydrate to an insolubilization treatment; and immersing the sapphire substrate having the insolubilized layer in a reaction solution containing a metal ion and an NH₄⁺ ion, so as to grow rod-shaped crystals each containing metal oxide as a main substance thereof.
<2> The method for producing a metal oxide structure according to <1>, wherein the insolubilization treatment is a heat treatment.
<3> The method for producing a metal oxide structure according to <2>, wherein in the heat treatment, a heat temperature is 30° C. to 300° C. and a heat time is 30 seconds to 30 hours.
<4> The method for producing a metal oxide structure according to any one of <1> to <3>, wherein the metal acetate hydrate is zinc acetate dihydrate.
<5> The method for producing a metal oxide structure according to any one of <1> to <4>, further including heating the sapphire substrate on which the rod-shaped crystals are formed after the immersing the sapphire substrate.
<6> A metal oxide structure obtained by the method for producing the metal oxide structure according to any one of <1> to <5>, including: a sapphire substrate; and rod-shaped crystals formed standing upright on the sapphire substrate, wherein a long axis of each of the rod-shaped crystals is oriented with respect to a perpendicular line to the sapphire substrate within ±5°, and an average diameter of short axes of the rod-shaped crystals is 500 nm or less.
<7> The metal oxide structure according to <6>, further including an intermediate layer containing metal acetate formed between the sapphire substrate and the rod-shaped crystals.
<8> The metal oxide structure according to <7>, wherein each of the rod-shaped crystals is a wurtzite-typed crystal structure, and a direction of the long axis of each of the rod-shaped crystals and a direction of a c-axis of the sapphire substrate are substantially equal.
<9> The metal oxide structure according to any one of <6> to <8>, wherein each of the rod-shaped crystals has a hexagonal rod shape, a whisker shape or a fiber shape.
<10> A light-emitting element including a light emitting part, wherein the light emitting part includes the metal oxide structure according to any one of <6> to <922 as a part thereof.

The present invention can solve the conventional problems and attain the above-described objects, and can provide a metal oxide structure which includes rod-shaped crystals formed on a substrate with high orientation and high density, and is useful as a light-emitting element, a high sensitive sensor, and the like, and a method for producing the metal oxide structure, and a light-emitting element.

### BRIEF DESCRIPTION OF THE DRAWINGS

FIG. 1A is an SEM image (top view) of a metal oxide structure produced in Example 1 (first).

FIG. 1B is an SEM image (top view) of a metal oxide structure produced in Example 1 (second).

FIG. 1C is an SEM image (cross sectional view) of a metal oxide structure produced in Example 1 (first).

FIG. 1D is an SEM image (cross sectional view) of a metal oxide structure produced in Example 1 (second).

FIG. 2 is an SEM image of a metal oxide structure produced in Comparative Example 1.

FIG. 3 is an SEM image of a metal oxide structure produced in Comparative Example 2.

FIG. 4 is an SEM image of a metal oxide structure produced in Comparative Example 3.

FIG. 5A is an SEM image (top view) of a metal oxide structure produced in Comparative Example 4.

FIG. 5B is an SEM image (cross sectional view) of a metal oxide structure produced in Comparative Example 4.

FIG. 6A is a graph showing a fluorescent emission intensity of a metal oxide structure (first).

FIG. 6B is a graph showing a fluorescent emission intensity of a metal oxide structure (second).

### DETAILED DESCRIPTION OF THE INVENTION

### (Metal Oxide Structure)

A metal oxide structure of the present invention contains a sapphire substrate, rod-shaped crystals formed standing upright on the sapphire substrate, and further contains other structural elements as necessary.

### —Sapphire Substrate—

The shape, structure, size and the like of the sapphire substrate are not particularly limited and may be suitably selected depending on the intended purpose. The shape may be a plate shape, or the like. The structure may be a single layer structure or a multi-layer structure, and may be suitably selected depending on the intended purpose.

A material of the sapphire substrate is not particularly limited as long as it is a single-crystalline sapphire, and may be suitably selected depending on the intended purpose. Examples thereof include a c-plane sapphire, a-plane sapphire and r-plane sapphire.

### —Rod-Shaped Crystal—

The rod-shaped crystals are formed standing upright on the sapphire substrate, specifically, the rod-shaped crystals are formed standing upright in a direction substantially perpendicular to the sapphire substrate surface. When the sapphire substrate is a c-plane sapphire, a long axis direction of each of the rod-shaped crystals and a c-axis direction of the sapphire substrate are substantially equal.

Here, when the sapphire substrate is a c-plane sapphire, “the rod-shaped crystals are formed standing upright in a direction substantially perpendicular to the sapphire substrate surface” means the long axis of each of the rod-shaped crystals is oriented with respect to a perpendicular line to the sapphire substrate surface, within ±5°, preferably ±1.5°.

It has been confirmed that when an angle formed by the long axis of each of the rod-shaped crystals and the perpendicular line to the sapphire substrate surface is changed, a fluorescent emission intensity which will be described hereinbelow is also changed.

Here, the formation of the rod-shaped crystals standing upright on the sapphire substrate can be confirmed by observing a cross section of the sapphire substrate using a scanning electron microscope (SEM) or a transmission electron microscope (TEM).

The orientation of the long axis of each of the rod-shaped crystals with respect to the perpendicular line to the sapphire substrate surface being within ±5°, preferably ±1.5° can be confirmed by measuring an angle formed by the long axis of each of the rod-shaped crystals and the perpendicular line with respect to the substrate surface, in a cross-sectional image of the portion near an interface between the substrate and the rod-shaped crystals, which is obtained using a scanning electron microscope (SEM) or a transmission electron microscope (TEM).

The rod-shaped crystals are not particularly limited as long as each of them contains metal oxide as a maim substance thereof, and may be appropriately selected depending on the intended purpose. The rod-shaped crystals of zinc oxide (ZnO) are preferably used. The rod-shaped crystals may contain a coexisting material which is not a main substance as well as a main substance constituting a part of the rod-shaped crystals. For example, the main substance of the rod-shaped crystals is zinc oxide (a wurtzite-typed crystal structure described hereinbelow), and the coexisting material may have a crystal structure different from the crystal structure of the main substance.

The metal oxide is not particularly limited and may be appropriately selected depending on the intended purpose. Examples thereof include zinc oxide, (ZnO), MgO, Al₂O₃, In₂O₃, SiO₂, SnO₂, TiO₂, barium titanate, SrTiO₃, PZT, YBCO (YBaCu₃O₇₋ₓ), YSZ (yttrium stabilized zirconia), YAG (Y₃Al₅O₁₂ or 3Y₂O₃.5Al₂O) and composite oxides and solid solutions thereof, such as ITO(In₂O₃/SnO₂) and Zn₁₋ₓMgₓO. Of these, zinc oxide (ZnO) is particularly preferred, in term of obtaining metal oxide having a high surface area and of no adverse affect on human body. The average diameter (average breadth) of short axes of the rod-shaped crystals is not particularly limited as long as it is 500 nm or less, and may be appropriately selected depending on the intended purpose. It is preferably 1 nm to 490 nm.

When the average diameter of the short axes of the rod-shaped crystals (average breadth) is more than 500 nm, a rod obtained finally after the growth reaction becomes thick, and the surface area of the metal oxide layer finally obtained is decreased. Thus, the sensitivity of the metal oxide structure used as a sensor may be decreased.

Here, the average diameter (average breadth) of the short axes of the rod-shaped crystals is defined as follows: when the cross sections perpendicular to the longitudinal direction of the rod-shaped crystals are circular, the average diameter means an average diameter of the cross-sections; and when the cross sections perpendicular to the longitudinal direction of the rod-shaped crystals are not circular, the average diameter means an average of the longest straight lines connecting together two points on the periphery of the cross sections. The average diameter can be measured in such a manner that the short axes of the rod-shaped crystals are observed using a scanning electron microscope (SEM) or a transmission electron microscope (TEM), and from the obtained image the average breadth is measured using a vernier caliper or an image analysis device. The rod-shaped crystals may be observed either along with the sapphire substrate or in a state where they are separated from the sapphire substrate.

The length of the long axis of each of the rod-shaped crystals is not particularly limited and may be appropriately selected depending on the intended purpose. It is preferably 0.1 μm to 10 μm, more preferably 1 μm to 5 μm.

The shape of each of the rod-shaped crystals is not particularly limited and may be appropriately selected depending on the intended purpose. It is preferably a hexagonal rod shape, a whisker shape or a fiber shape.

The structure of each of the rod-shaped crystals is not particularly limited and may be appropriately selected depending on the intended purpose. It is preferably a wurtzite-typed crystal structure. The wurtzite-typed crystal structure is one of crystal structures which can be seen in an ion crystal formed by bonding an anion and a cation in the ratio of 1:1. The wurtzite-typed crystal structure may be formed not only when the rod-shaped crystals are ZnO, but also when the rod-shaped crystals are metal-doped ZnO, for example, Zn_{1-X}Mg_{X}O. The rod-shaped crystals are measured by X-ray diffraction so as to find out whether or not the structure of each of the rod-shaped crystals is the wurtzite-typed crystal structure.

The density of the rod-shaped crystals is not particularly limited as long as the number of the rod-shaped crystals is 10 or more per 1 μm² of the sapphire substrate, and may be appropriately selected depending on the intended purpose. It is preferably 20 or more, more preferably 30 or more, and particularly preferably 40 or more, per 1 μm² of the sapphire substrate.

When the density of the rod-shaped crystals is less than 10 rod-shaped crystals per 1 μm² of the sapphire substrate, the surface area of the final metal oxide layer is decreased, and the sensitivity of the metal oxide structure used as a sensor may be decreased. Additionally, an emission intensity of the metal oxide structure used as a light-emitting element may be decreased.

Here, the density of the rod-shaped crystals can be measured in such a manner that the rod-shaped crystals are observed using a scanning electron microscope (SEM) or a transmission electron microscope (TEM), and from the obtained image (top view) the density of the rod-shaped crystals is measured using an image analysis device, or the like.

A method for depositing (growing) the rod-shaped crystals on the sapphire substrate is not particularly limited and may be appropriately selected depending on the intended purpose. For example, a crystal growth method in an aqueous solution, in which the substrate is immersed in a reaction solution which enables the rod-shaped crystals to deposit, so as to deposit the rod-shaped crystals thereon, is preferably used, because the method does not use an expensive equipment and can be performed at low cost and low temperature process. The method for growing the rod-shaped crystals will be described in a method for producing a metal oxide structure described below.

### —Other Structural Elements—

The other structural elements are not particularly limited and may be appropriately selected depending on the intended purpose. Examples thereof include an intermediate layer (template layer).

### —Intermediate Layer (Template Layer)—

The intermediate layer (template layer) is not particularly limited as long as it contains metal acetate, and may be appropriately selected depending on the intended purpose.

The metal acetate is not particularly limited and may be appropriately selected depending on the intended purpose. Examples thereof include zinc acetate.

In the metal oxide structure of the present invention, an intermediate layer (template layer) containing the metal acetate is formed in a production process. When the rod-shaped crystals are deposited (grown), all or part of the metal acetate contained in the intermediate layer (template layer) is decomposed into metal oxide by hydrolysis reaction expressed by Formula 1, which is described in X. L. Hu, Y. Masuda, T. Ohji and K. Kato, Langmuir, 24, 7614-7617 (2008). This metal oxide becomes part of the rod-shaped crystal and may not be differentiated from the rod-shaped crystal, or may be differentiated therefrom.

Zn(CH₃COO)₂(anhydride)30 20H⁻→ZnO+2CH₃COO⁻+H₂O Formula 1

The thickness of the intermediate layer (template layer) is not particularly limited and may be appropriately selected depending on the intended purpose. It is preferably 1 nm to 800 nm, more preferably 5 nm to 400 nm, and particularly preferably 10 nm to 100 nm.

When the thickness of the intermediate layer (template layer) is less than 1 nm, the whole intermediate layer may be dissolved during a crystal growth process. When it is more than 800 nm, although the crystals can grow, the grown crystals may be irregularly oriented.

Here, the thickness of the intermediate layer (template layer) can be measured in such a manner that the intermediate layer (template layer) is observed using a scanning electron microscope (SEM) or a transmission electron microscope (TEM), and then the thickness of the intermediate layer (template layer) is measured. However, in the case where the intermediate layer (template layer) is so thin, it cannot be measured by the observation with a standard scanning electron microscope (SEM) or transmission electron microscope (TEM). In this case, the thin intermediate layer (template layer) is measured using a high resolution transmission electron microscope or the like.

A method for forming the intermediate layer (template layer) on the sapphire substrate surface is not particularly limited and may be appropriately selected depending on the intended purpose. For example, a method, in which a coating solution obtained by dissolving metal acetate hydrate in a solvent is applied to a sapphire substrate surface, and subjected to insolubilization treatment such as heat treatment or the like, is used.

### (Method for Producing Metal Oxide Structure)

A method for producing a metal oxide structure of the present invention includes at least a layer forming step, an insolubilization treatment step, and a growth step, and further includes other steps such as a postgrowth heating step.

### <Layer Forming Step>

The layer forming step is a step of forming a layer containing metal acetate hydrate on a sapphire substrate.

The layer is formed, for example, by applying a coating solution containing metal acetate hydrate over the sapphire substrate.

The coating solution contains metal acetate hydrate, a solvent, and other components, as necessary.

The metal acetate hydrate is not particularly limited and may be appropriately selected depending on the intended purpose. Examples thereof include zinc acetate dihydrate. The solvent is not particularly limited and may be appropriately selected depending on the intended purpose. Examples thereof include anhydrous ethanol, anhydrous methanol, and 2-methoxyethanol. Of these, anhydrous ethanol is preferred in terms of handleability.

A coating method is not particularly limited and may be appropriately selected depending on the intended purpose. Examples thereof include a spin coating, casting, roll coating, flow coating, printing, dip coating, film deposition by flow casting, bar coating, and gravure printing. A coating amount of the coating solution changes depending on a solid content of the coating solution. The coating amount is preferably 800 nm or less, more preferably 5 nm to 400 nm, particularly preferably 10 nm to 100 nm, based on the solid film thickness.

### <Insolubilization Treatment Step>

The insolubilization treatment step is a step of subjecting the layer containing the metal acetate hydrate to an insolubilization treatment.

The insolubilization treatment is not particularly limited, as long as it is a treatment in which the layer containing the metal acetate hydrate is insolubilized to the reaction solution described below, and may be appropriately selected depending on the intended purpose. Examples thereof include heat treatment. When the insolubilization treatment is not performed, the metal acetate hydrate contained in the layer may be dissolved in the reaction solution described below, for example, as expressed by Formula 2.

Zn(CH₃COO)₂.2H₂O→Zn²⁺+2CH₃COO⁻2H₂O Formula 2

However, by the insolubilization treatment, the metal acetate hydrate contained in the layer is dehydrated and formed into anhydrous metal acetate. Thus, the solubility to the reaction solution described below is decreased.

For example, the solubility of the zinc acetate layer to the reaction solution is decreased due to dehydration of hydrate. Even if a small amount of the zinc acetate layer is dissolved in the reaction solution, a zinc oxide layer is formed before the zinc acetate layer is not completely dissolved therein. Thus, “insolubilization” includes not only complete insolubilization to the reaction solution by dehydration of hydrate, but also decrease in solubility to the reaction solution.

### <<Heat Treatment>>

The heat treatment is not particularly limited and may be appropriately selected depending on the intended purpose. Examples thereof include heating in an oven.

A heat temperature in the heat treatment is not particularly limited and may be appropriately selected depending on the intended purpose. It is preferably 35° C. to 300° C., more preferably 40° C. to 150° C., and particularly preferably 45° C. to 110° C.

When the heat temperature in the heating treatment is lower than 35° C., the hydration water in metal acetate hydrate may not be dehydrated. When the heat temperature in the heat treatment is higher than 300° C., the substrate may be deformed.

The heat time in the heat treatment is not particularly limited and may be appropriately selected depending on the intended purpose. The heat time is preferably 30 seconds to 30 hours, and more preferably 10 minutes to 28 hours, and particularly preferably 20 minutes to 24 hours.

The heat time in the heat treatment is less than 30 seconds, the hydration water in metal acetate hydrate may not be dehydrated. When the heat time in the heat treatment is more than 30 hours, even though the insolubilization treatment can be performed, the surface structure is roughened, and large irregularities may be formed on the surface.

The insolubilization treatment is not limited to the heat treatment, but may be a treatment in which heat is generated spontaneously, having an effect of removing all or a part of hydrate from the metal acetate hydrate.

### <Growth Step>

The growth step is a step of immersing the sapphire substrate having the insolubilized layer in a reaction solution containing a metal ion and an NH₄⁺ ion, so as to grow rod-shaped crystals each containing metal oxide as a main substance thereof.

A metal of the metal ion is not particularly limited and may be appropriately selected depending on the intended purpose. Zn is preferred as a metal.

The reaction solution is not particularly limited as long as it can deposit rod-shaped crystals, and may be appropriately selected depending on the intended purpose. The reaction solution contains a metal oxide source, a complexing agent, a solvent, a pH adjuster, and the like.

The metal oxide source can be appropriately selected depending on the types of rod-shaped crystals which are deposited on the substrate. For example, Zn, salts of Zn, Zn hydroxide, or Zn hydrate can be used when zinc oxide (ZnO) is grown.

Examples of salts of Zn include Zn sulfate (such as ZnSO₄), Zn nitrate (such as Zn(NO₃)₂), Zn chloride (such as ZnCl₂), Zn acetate (such as Zn(CH₃COO)₂), and hydrates thereof.

The solvent is not particularly limited and may be appropriately selected depending on the intended purpose. Examples thereof include water, methanol, ethanol and isopropyl alcohol.

The complexing agent is not particularly limited and may be appropriately selected depending on the intended purpose. Examples thereof include ammonium chloride, ammonium nitrate, and ammonium sulfate.

The pH of the reaction solution is not particularly limited and may be appropriately selected depending on the intended purpose. It is preferably 8.0 to 12.5, and more preferably 9.0 to 12.0. The pH of the reaction solution is adjusted using the pH adjuster. The pH adjuster is not particularly limited and may be appropriately selected depending on the intended purpose. Examples thereof include NaOH, KOH, NH₄OH, and triethanolamine.

The temperature of the reaction solution is preferably 40° C. to 95° C., and more preferably 50° C. to 85° C.

The immersion of the sapphire substrate is not particularly limited and may be appropriately selected depending on the intended purpose. The sapphire substrate is preferably immersed with the surface on which the crystals are grown, i.e. on which a layer is formed, facing downward.

### <Postgrowth Heating Step>

The postgrowth heating step is a step of heating the metal oxide structure after the growth step.

The heat temperature of the postgrowth heating step is not particularly limited and may be appropriately selected depending on the intended purpose. It is preferably 250° C. to 800° C., more preferably 300° C. to 700° C., and particularly preferably 350° C. to 600° C.

When the heat temperature of the postgrowth heating step is lower than 250° C., the crystallinity of the metal oxide may not be increased, and oxygen vacancy may occur. When it is higher than 800° C., the substrate may be deformed.

The heat time of the postgrowth heating step is not particularly limited and may be appropriately selected depending on the intended purpose. It is preferably 5 minutes to 24 hours, and more preferably 10 minutes to 12 hours, and particularly preferably 30 minutes to 6 hours.

When the heat time in the postgrowth heating step is less than 5 minutes, the crystallinity of the metal oxide may not be increased, and oxygen vacancy may occur. When it is more than 24 hours, the substrate may be deformed.

A method for producing the metal oxide structure of the present invention can be performed in “one pot.” Since this is a system using a complexing agent (NH₄Cl), the value of pH which has been adjusted before crystal growth is hardly changed during crystal growth and after completion of crystal growth. When the pH value is hardly changed, rod-shaped crystals in a shape of hexagonal rod, whisker or fiber can be effectively produced in “one pot”.

### —Application—

In the metal oxide structure of the present invention, rod-shaped crystals are substantially vertically arranged on a substrate. The metal oxide structure of the present invention can be used for electronic materials such as an insulator, an electric conductor, a solid electrolyte, a fluorescent display tube, an electroluminescence element, a ceramic condenser, an actuator, a laser oscillation element, a cold cathode element, a ferroelectric memory, a piezoelectric body, a thermistor, a varistor, a superconductor, a printed board, optical elements such as an electromagnetic shielding material, an optical dielectric, an optical switch, an optical sensor, a solar battery, an optical wavelength conversion element, a light absorption filter, sensors such as a temperature sensor, a gas sensor, a biological diagnostic material, a surface modifier, a surface protective agent, a antireflection agent, a surface modifier for the purpose of antibacterial and antifouling effect, a catalyst in at least one of gas phase and liquid phase, or carriers thereof.

Of these, the rod-shaped crystals each having an average diameter (average breadth) of the short axes of 500 nm or less can be preferably used as a sensor which will be described below, because such thin rod-shaped crystals can be formed standing upright on the substrate so as to obtain large surface area to thereby obtain high sensitivity.

The sensor is not particularly limited and may be appropriately selected depending on the intended purpose. A gas sensor is preferably used.

A sensing method in the gas sensor is not particularly limited and may be appropriately selected depending on the intended purpose. Examples thereof include a method using electric resistance, an optical sensing, a method of analyzing weight, and concentration of gas passing through the gas sensor. Of these, the method of using electric resistance is preferred.

The measurement using electric resistance is to measure variation in the electric resistance of the metal oxide structure in a detecting atmosphere in which a temperature condition is specified. In the atmosphere, a gas detector is installed and operated, and gas molecules are adsorbed on a surface of the metal oxide structure, to thereby change an electric resistance. Generally, the range of variation in the electric resistance is decided depending on the concentration or content of a detected gas.

### (Light-Emitting Element)

A light-emitting element of the present invention includes the metal oxide structure of the present invention, and a rod-shaped crystal part of the metal oxide structure serves as a light emitting part.

The light-emitting element is not particularly limited and may be appropriately selected depending on the intended purpose.

### Examples

Hereinafter, the present invention will be explained by way of Examples, which should not be construed as limiting the present invention thereto.

In Examples and Comparative Examples, “an average diameter (average breadth) of short axes of rod-shaped crystals”, “an average length of long axes of the rod-shaped crystals” and “an angle formed by the long axis of each of the rod-shaped crystals and a perpendicular line to a substrate surface” were measured as follows.

### <Measurement of Average Diameter (Average Breadth) of Short Axes of Rod-Shaped Crystals>

From an image obtained using a scanning electron microscope (SEM) or a transmission electron microscope (TEM), 50 rod-shaped crystals were randomly selected. The sizes of the rod-shaped crystals were measured and an average breadth thereof was calculated. Within the entire rod-shaped crystal, the longest breadth of the short axis of the rod-shaped crystal was measured.

### <Measurement of Average Length of Long Axes of Rod-Shaped Crystals>

From an image obtained using a scanning electron microscope (SEM) or a transmission electron microscope (TEM), 50 rod-shaped crystals were randomly selected. The sizes of the rod-shaped crystals were measured and an average length of the long axis was calculated. The length of the longest straight line connecting both ends of each rod-shaped crystal was measured.

The average length of ZnO rod-shaped crystals and the thickness of the ZnO rod-shaped crystal layer, shown in Table 1, were not necessarily equal. This is because a ZnO layer formed from an intermediate layer might be present as a part of the rod-shaped crystals or the rod-shaped crystals might be formed obliquely on the substrate. The average length of the ZnO rod-shaped crystals and the thickness of the ZnO rod-shaped crystal layer, shown in Table 1, were equal, only when the ZnO rod-shaped crystals were formed completely vertically on the substrate and the ZnO rod-shaped crystal layer formed from the intermediate layer was not present (could not be seen) as a part of the rod-shaped crystals.

### <Angle Formed by Long Axes of Rod-Shaped Crystals and Perpendicular Line to Substrate Surface>

From a cross-sectional image of the portion near an interface between the substrate and the rod-shaped crystals obtained using a scanning electron microscope

(SEM) or a transmission electron microscope (TEM), an angle formed by the long axes of the rod-shaped crystals and a perpendicular line with respect to the substrate surface was measured.

### Example 1

### —Production of Metal Oxide Structure—

Zinc acetate dihydrate (Zn(CH₃COO)₂.2H₂O, 99%) (manufactured by Wako Pure Chemical Industries, Ltd.) was dissolved in dehydrated ethanol (manufactured by Wako Pure Chemical Industries, Ltd.) to produce a 0.01 M coating solution. The produced coating solution was applied to a c-plane sapphire substrate (manufactured by KYOCERA Corporation) using a spin coater (manufactured by MIKASA CO., LTD.) at 1,000 rpm for 30 min. Then, the c-plane sapphire substrate was left to stand for drying for 12 hours at room temperature, and then heated in an oven at 65° C. for 24 hours to thereby obtain a c-plane sapphire substrate on which an intermediate layer (template layer) was formed.

Next, ZnSO₄.7H₂O as a metal oxide source was dissolved into water with stirring for 1 hour, so that the water contained a [Zn²⁺] concentration of 0.02 M. In the solution, NH₄Cl as a complexing agent was added so as to satisfy the equation R═[NH₄⁺]/[Zn²⁺]=30, and then stirred for 30 min, to thereby prepare a base liquid with a [Zn²⁺] concentration of 0.02 M.

In the obtained base liquid, water and a NaOH aqueous solution were added so as to obtain a [Zn²⁺] concentration of 0.01 M and pH of 11.0, to thereby prepare a solution for ZnO crystal growth.

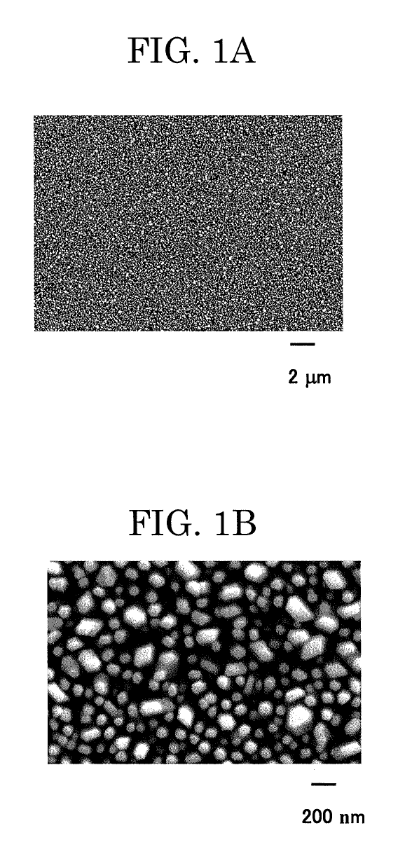

Subsequently, in the solution for ZnO crystal growth, the c-plane sapphire substrate on which the intermediate layer (template layer) had been formed was placed with the intermediate layer (template layer) facing downward, the solution was adjusted to 60° C., and the c-plane sapphire substrate was left for standing for 24 hours in an oven while the solution was kept at 60° C., so as to grow ZnO crystals (growth step). Then, the substrate was taken out from the solution and dried. The dried metal oxide structure was observed using a field emission scanning electron microscope (SEM) (S-4300 manufactured by Hitachi, Ltd.) and the X-ray diffraction measurement thereof was performed using an X-ray diffractometer (XRD, RINT-2000, manufactured by Rigaku Corporation). It was confirmed that the ZnO rod-shaped crystals were formed standing upright on the c-plane sapphire substrate, and that an angle formed by a perpendicular line to a c-plane sapphire substrate surface and a long axis of each of the ZnO rod-shaped crystals was within ±5° (FIGS. 1A to 1D).

The obtained ZnO rod-shaped crystals had an average breadth of 118 nm and an average length of 4.2 μm.

### —Measurement of Fluorescent Emission Intensity—

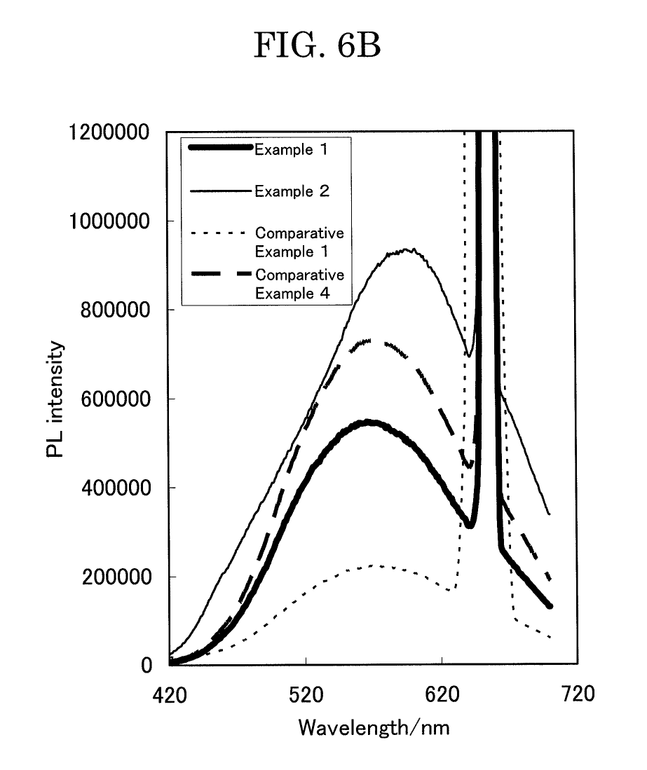

The produced metal oxide structure was irradiated with a light having a wavelength of 325 nm using a spectrofluorometer SPEX Fluorolog-3 (manufactured by HORIBA Ltd.) to be excited, to thereby measure fluorescent emission intensity of the metal oxide structure at each wavelength. The results are shown in FIGS. 6A and 6B and Table 1.

### Example 2

A metal oxide structure was produced in the same manner as in Example 1, except that the metal oxide structure obtained in Example 1 was further fired in air at 500° C. for 1 hour.

The produced metal oxide structure was observed using the field emission scanning electron microscope (SEM) (S-4300 manufactured by Hitachi, Ltd.) and the X-ray diffraction measurement thereof was performed using an X-ray diffractometer (XRD, RINT-2000, manufactured by Rigaku Corporation). It was confirmed that ZnO rod-shaped crystals were formed standing upright on the c-plane sapphire substrate, and that an angle formed by a perpendicular line to a c-plane sapphire substrate surface and a long axis of each of the ZnO rod-shaped crystals was within ±5°.

The obtained ZnO rod-shaped crystals had an average breadth of 109 nm and an average length of 4.2 μm.

The fluorescent emission intensity of the metal oxide structure produced in Example 2 was measured. The results are shown in FIGS. 6A and 6B and Table 1.

### Comparative Example 1

A metal oxide structure was produced in the same manner as in Example 1, except that instead of the c-plane sapphire substrate on which the intermediate layer (template layer) was formed of Example 1, a c-plane sapphire substrate on which no intermediate layer (template layer) was formed was placed in the solution for ZnO crystal growth.

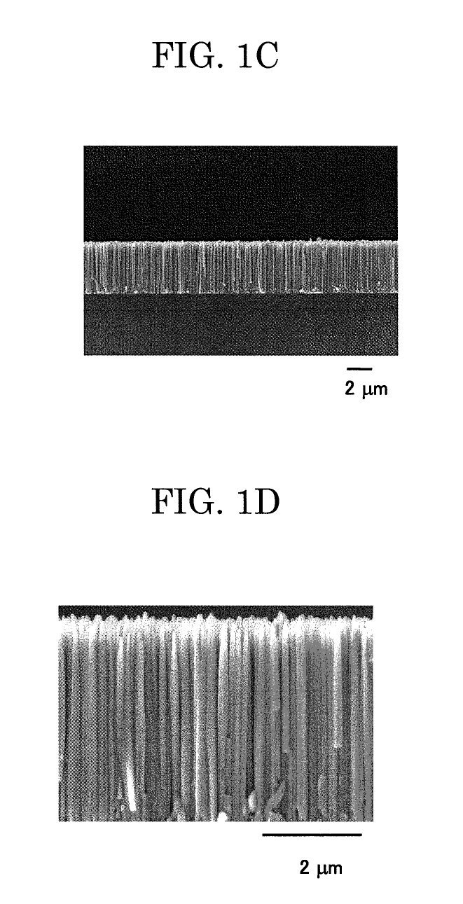

The produced metal oxide structure was observed using the field emission scanning electron microscope (SEM) (S-4300 manufactured by Hitachi, Ltd.). As a result, it was found that no ZnO rod-shaped crystal was formed standing upright on the c-plane sapphire substrate (FIG. 2).

The fluorescent emission intensity of the metal oxide structure produced in Comparative Example 1 was measured. The results are shown in FIGS. 6A and 6B and Table 1.

### Comparative Example 2

A metal oxide structure was produced in the same manner as in Example 1, except that instead of the c-plane sapphire substrate on which the intermediate layer (template layer) was formed of Example 1, a Si (100) substrate having a SiO₂ layer on which no intermediate layer (template layer) was formed was placed in the solution for ZnO crystal growth.

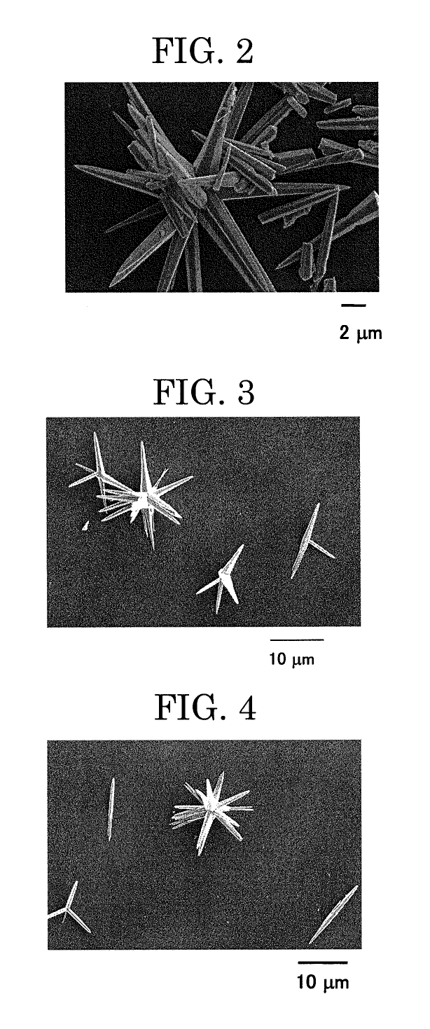

The produced metal oxide structure was observed using the field emission scanning electron microscope (SEM) (S-4300 manufactured by Hitachi, Ltd.). As a result, it was found that no ZnO rod-shaped crystal was formed standing upright on the Si (100) substrate having a SiO₂ layer (FIG. 3).

### Comparative Example 3

A metal oxide structure was produced in the same manner as in Example 1, except that a Si (100) substrate having a SiO₂ layer was used instead of the c-plane sapphire substrate (manufactured by KYOCERA Corporation), and that the Si (100) substrate having a SiO₂ layer was left to stand for drying at room temperature without heating at 65° C. for 24 hours, instead it was left to stand for drying at room temperature and heated at 65° C. for 24 hours as in Example 1.

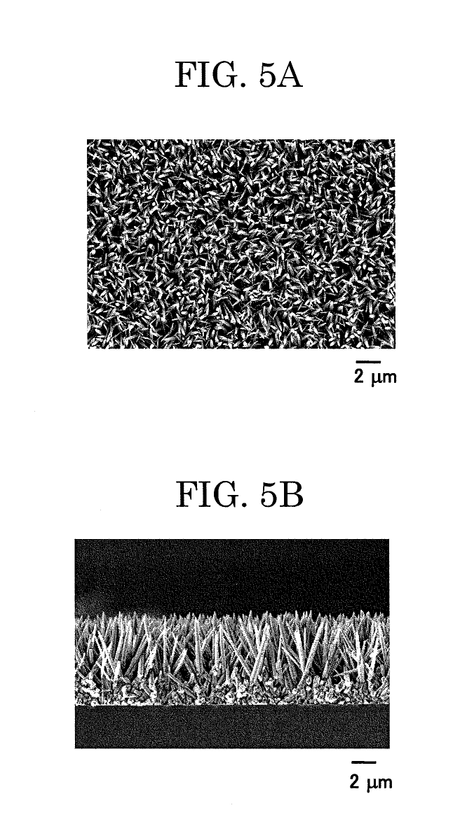

The produced metal oxide structure was observed using the field emission scanning electron microscope (SEM) (S-4300 manufactured by Hitachi, Ltd.). As a result, it was found that no ZnO rod-shaped crystal was formed standing upright on the Si (100) substrate having a SiO₂ layer (FIG. 4).

### Comparative Example 4

A metal oxide structure was produced in the same manner as in Example 1, except that a Si (100) substrate having a SiO₂ layer was used instead of the c-plane sapphire substrate (manufactured by KYOCERA Corporation) in Example 1.

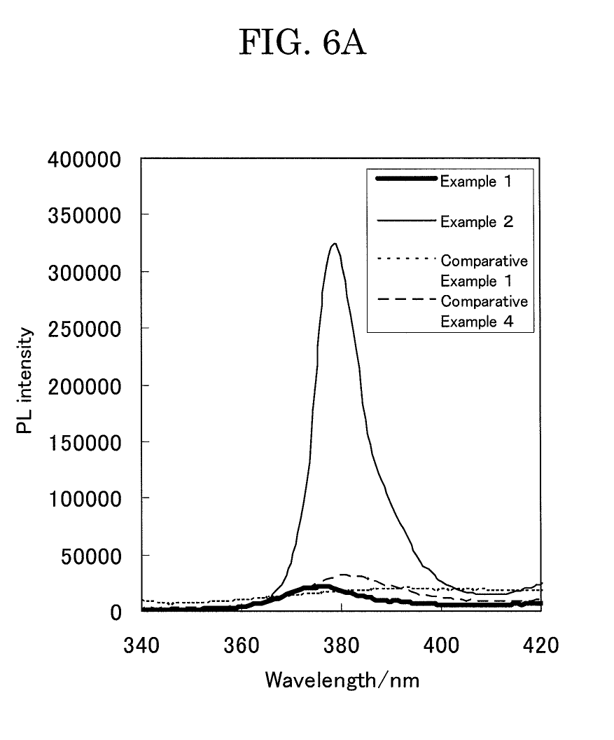

The produced metal oxide structure was observed using the field emission scanning electron microscope (SEM) (S-4300 manufactured by Hitachi, Ltd.) and the X-ray diffraction measurement thereof was performed using an X-ray diffractometer (XRD, RINT-2000, manufactured by Rigaku Corporation). As a result, it was found that no ZnO rod-shaped crystal was formed standing upright on the Si (100) substrate having a SiO₂ layer, and that an angle formed by a perpendicular line to the Si (100) substrate surface having a SiO₂ layer and a long axis of each of the ZnO rod-shaped crystals was not within ±5° (FIGS. 5A and 5B). Meanwhile, it was considered that a layer formed between the ZnO rod-shaped crystals and the substrate was a layer of the zinc oxide particles which had been changed from a zinc acetate.

The obtained ZnO rod-shaped crystals had an average breadth of 213 nm and an average length of 5.31 μm.

The fluorescent emission intensity of the metal oxide structure produced in Comparative Example 4 was measured. The results are shown in FIGS. 6A and 6B and Table 1.

### Comparative Example 5

A metal oxide structure produced in the same manner as in Example 1, except that the c-plane sapphire substrate on which the intermediate layer (template layer) had been formed was left to stand for drying at room temperature without heating at 65° C. for 24 hours, instead it was left to stand for drying at room temperature and heated at 65° C. for 24 hours as in Example 1.

The produced metal oxide structure was observed using the field emission scanning electron microscope (SEM) (S-4300 manufactured by Hitachi, Ltd.) and the X-ray diffraction measurement thereof was performed using the X-ray diffractometer (XRD, RINT-2000, manufactured by Rigaku Corporation). The result was the same as that in Comparative Example 1. Namely, it was found that only a small amount of the ZnO rod-shaped crystals was deposited on the c-plane sapphire substrate, but not in a standing upright state, and that an angle formed by a perpendicular line to the c-plane sapphire substrate surface and a long axis of each of the ZnO rod-shaped crystals was not within ±5°.

Next, the production conditions of Examples 1 to 2 and Comparative Examples 1 to 5 and the measurement results are shown in Table 1.

TABLE 1

| | Ex. 1 | Ex. 2 | Comp. Ex. 1 | Comp. Ex. 2 | Comp. Ex. 3 | Comp. Ex. 4 | Comp. Ex. 5 |
|---|---|---|---|---|---|---|---|
| Composition of metal oxide | ZnO | ZnO | ZnO | ZnO | ZnO | ZnO | ZnO |
| Substrate | c-plane | c-plane | c-plane | Si(100) | Si(100) | Si(100) | c-plane |
| | sapphire | sapphire | sapphire | substrage | substrage | substrage | sapphire |
| | substrate | substrate | substrate | having SiO₂ | having SiO₂ | having SiO₂ | substrate |
| | (single crystal) | (single crystal) | (single crystal) | layer | layer | layer | (single crystal) |
| Intermediate layer | zinc acetate | zinc acetate | — | — | zinc acetate | zinc acetate | zinc acetate |
| | dihydrate | dihydrate | | | dihydrate | dihydrate | dihydrate |
| Treatment condition of | Dried at room | Dried at room | — | — | Only dried | Dried at room | Only dried |
| intermediate layer | temperature and | temperature and | | | at room | temperature and | at room |
| | then heated at | then heated at | | | temperature | then heated at | temperature |
| | 65° C. for 24 hr | 65° C. for 24 hr | | | | 65° C. for 24 hr | |
| Angle formed by | within ±5° | within ±5° | — | — | — | outside ±5° | — |
| perpendicular line | | | | | | | |
| and long axis | | | | | | | |
| Average length (μm) | 4.2 | 4.2 | — | — | — | 5.31 | — |
| Average breadth (nm) | 118 | 109 | — | — | — | 213 | — |
| Thickness of rod-shaped | 4.2 | 4.2 | — | — | — | 7.1 | — |
| crystal layer (μm) | | | | | | | |
| Peak intensity ratio | 3.9 | 25.8 | 7.9 | — | — | 4.2 | — |
| Intensity ratio equivalent | 3.9 | 25.8 | — | — | — | 2.5 | — |
| to thickness 4.2 μm | | | | | | | |

“Thickness of rod-shaped crystal layer” in Table 1 was measured as follows.

### <<Method of Measuring Thickness of Rod-Shaped Crystal Layer>>

A cross-sectional image of a rod-shaped crystal layer was obtained using a scanning electron microscope (SEM), and from the cross-sectional image the thickness of rod-shaped crystal layer was measured at randomly selected 10 points and calculated. In the cross-sectional SEM image, the measurement value was a length of a straight line which connected the substrate surface and the outermost surface of the rod-shaped crystal layer, and was parallel to a perpendicular line with respect to the substrate surface.

In the case where when the rod-shaped crystals were deposited (grown), all or a part of the metal acetate contained in the intermediate layer (template layer) was decomposed into metal oxide and the metal oxide constituted a part of the rod-shaped crystals, the rod-shaped crystal layer included the part of the rod-shaped crystals formed from the intermediate layer. Namely, the rod-shaped crystal layer included ZnO formed from the intermediate layer and ZnO rod-shaped crystals formed thereon. On the other hand, in the case where a layer of metal oxide, which was formed by decomposition of metal acetate by hydrolysis reaction, could be differentiated from the rod-shaped crystal layer, the rod-shaped crystal layer included the layers of metal oxide and the rod-shaped crystals.

The “peak intensity ratio” in Table 1 was calculated from the following formula:

I_{A}/(I_{A}+I_{B})×100

where I_{A} represents the maximum peak intensity within the wavelength range of 340 nm or more to less than 420 nm (FIG. 6A), and I_{B} represents the maximum peak intensity within the wavelength range of 420 nm to 720 nm (FIG. 6B). In FIG. 6B, a peak within the wavelength range of 620 nm to 720 nm is not a peak based on a sample of the metal oxide structure. This peak should not be taken as the maximum peak.

The “intensity ratio equivalent to thickness 4.2 μm” was a value obtained by calculating a peak intensity ratio by the Equation: I_{A}/(I_{A}+I_{B})×100, and converting the intensity ratio equivalent to the thickness of the rod-shaped crystal layer being 4.2 μm. For example, since in Examples 1 and 2, the thickness of the rod-shaped crystal layer was 4.2 μm, each value was the peak intensity ratio per se, i.e., 3.9 and 25.8, and in Comparative Example 4, the peak intensity ratio was 2.5 obtained by calculating from the formula: 4.2×4.2/7.1.

The value of “peak intensity ratio” increased according to the increase in the thickness of the rod-shaped crystal layer. In samples of the metal oxides having the same thicknesses of the rod-shaped crystal layers, the larger the “peak intensity ratio” of the metal oxide sample was, the closer to the single crystal it was, namely, less defect it had.

Thus, since the “intensity ratio equivalent to the thickness 4.2 μm” of Examples 1 and 2 was larger than that of Comparative Example 4, it had been found that the metal oxide structures of Examples 1 and 2 were closer to a single crystal having no defect (a crystal having less defect) than that of Comparative Example 4.

The metal oxide structure of the present invention can be used for electronic materials such as an insulator, an electric conductor, a solid electrolyte, a fluorescent display tube, an electroluminescence element, a ceramic condenser, an actuator, a laser oscillation element, a cold cathode element, a ferroelectric memory, a piezoelectric body, a thermistor, a varistor, a superconductor, a printed board, optical elements such as an electromagnetic shielding material, an optical dielectric, an optical switch, an optical sensor, a solar battery, an optical wavelength conversion element, a light absorption filter, sensors such as a temperature sensor, a gas sensor, a biological diagnostic material, a surface modifier, a surface protective agent, a antireflection agent, a surface modifier for the purpose of antibacterial and antifouling effect, a catalyst in at least one of gas phase and liquid phase, or carriers thereof. Particularly, the metal oxide structure of the present invention is preferably used for a gas sensor.

What is claimed is:

1. A method for producing a metal oxide structure, comprising:
forming a layer containing metal acetate hydrate on a sapphire substrate;
subjecting the layer containing the metal acetate hydrate to an insolubilization treatment; and
immersing the sapphire substrate having the insolubilized layer in a reaction solution containing a metal ion and an NH₄⁺ ion, so as to grow rod-shaped crystals each containing metal oxide as a main substance thereof.

2. The method for producing a metal oxide structure according to claim 1, wherein the insolubilization treatment is a heat treatment.

3. The method for producing a metal oxide structure according to claim 2, wherein in the heat treatment, a heat temperature is 30° C. to 300° C. and a heat time is 30 seconds to 30 hours.

4. The method for producing a metal oxide structure according to claim 1, wherein the metal acetate hydrate is zinc acetate dihydrate.

5. The method for producing a metal oxide structure according to claim 1, further comprising heating the sapphire substrate on which the rod-shaped crystals are formed after the immersing the sapphire substrate.

6. A metal oxide structure obtained by a method for producing a metal oxide structure, comprising:
a sapphire substrate; and
rod-shaped crystals formed standing upright on the sapphire substrate,
wherein a long axis of each of the rod-shaped crystals is oriented with respect to a perpendicular line to the sapphire substrate within ±5°, and an average diameter of short axes of the rod-shaped crystals is 500 nm or less, and
wherein the method for producing the metal oxide structure, comprises:
forming a layer containing a metal acetate hydrate on the sapphire substrate;
subjecting the layer containing the metal acetate hydrate to an insolubilization treatment; and
immersing the sapphire substrate having the insolubilized layer in a reaction solution containing a metal ion and an NH₄⁺ ion, so as to grow the rod-shaped crystals each containing metal oxide as a main substance thereof.

7. The metal oxide structure according to claim 6, further comprising an intermediate layer containing metal acetate formed between the sapphire substrate and the rod-shaped crystals.

8. The metal oxide structure according to claim 7, wherein each of the rod-shaped crystals is a wurtzite-typed crystal structure, and a direction of the long axis of each of the rod-shaped crystals and a direction of a c-axis of the sapphire substrate are substantially equal.

9. The metal oxide structure according to claim 6, wherein each of the rod-shaped crystals has a hexagonal rod shape, a whisker shape or a fiber shape.

10. A light-emitting element comprising:
a light emitting part,
wherein the light emitting part contains a metal oxide structure as a part thereof, the metal oxide structure being obtained by a method for producing the metal oxide structure, comprising:
a sapphire substrate; and
rod-shaped crystals formed standing upright on the sapphire substrate,
wherein a long axis of each of the rod-shaped crystals is oriented with respect to a perpendicular line to the sapphire substrate within ±5°, and an average diameter of short axes of the rod-shaped crystals is 500 nm or less, and
wherein the method for producing the metal oxide structure, comprises:
forming a layer containing a metal acetate hydrate on the sapphire substrate;
subjecting the layer containing the metal acetate hydrate to an insolubilization treatment; and
immersing the sapphire substrate having the insolubilized layer in a reaction solution containing a metal ion and an NH₄⁺ ion, so as to grow the rod-shaped crystals each containing metal oxide as a main substance thereof.
